(19) United States
(12) Patent Application Publication
(10) Pub. No.: US 2026/0149360 A1
(43) Pub. Date: May 28, 2026

(54) RIPPLE CANCELLATION IN SWITCHED-MODE VOLTAGE CONVERTERS

(71) Applicant: Texas Instruments Incorporated, Dallas, TX (US)

(72) Inventors: Hariharan Srinivasan, Chennai (IN); Gautam Nandi, Bangalore (IN)

(21) Appl. No.: 18/961,630

(22) Filed: Nov. 27, 2024

(51) Int. Cl. H02M 1/15; H02M 3/07; H02M 3/158; H03F 3/45

(52) U.S. Cl. CPC H02M 1/15; H02M 3/072; H02M 3/158; H03F 3/45273

(57) ABSTRACT

A voltage converter circuit includes a switched-mode voltage converter and a ripple cancellation circuit. The switched-mode voltage converter includes a first switching device having a first terminal coupled to a first power supply terminal, and a second switching device having a first terminal coupled to a second terminal of the first switching device, and a second terminal coupled to a second power supply terminal. The ripple cancellation circuit includes an op amp having a non-inverting input coupled to a load terminal; a first resistor coupled between the output of the op amp and an inverting input of the op amp; a second resistor coupled between the second terminal of the first switching device and the inverting input of the op amp; a first capacitor coupled in parallel with the first resistor; and a third resistor coupled between the output of the op amp and the load terminal.

### BACKGROUND

This specification relates to voltage converter circuits, and more particularly to switched-mode DC-DC “buck” or step-down converter circuits.

A voltage converter is an electric power converter which changes an input voltage from an electrical power source to another voltage level. Types of direct current (DC) voltage converters include linear power amplifiers and switched-mode voltage converters.

Linear power amplifiers are capable of generating stable and precise output voltages, even at relatively high output current levels. These capabilities favor the use of linear power amplifiers in precision electronic equipment. However, this precision and high output power from linear power amplifiers comes at a cost of high power dissipation, requiring significant heat removal or cooling capability in some system applications. For example, excessive power dissipation is an especially acute issue in automated test equipment (ATE), which can require multiple voltage converters on the same circuit board to provide different voltages and currents to individual pins of the device under test.

Switched-mode voltage converters, such as step-down or “buck” converters, are significantly more power efficient than linear amplifiers. The buck converter is a class of switched-mode power supply that periodically switches current applied to a storage element, such as an inductor or capacitor, producing an output voltage that is stepped-down from the input voltage. However, the periodic switching of current delivery to the storage element causes “ripple” in the output voltage. Significant ripple may preclude the use of switched-mode converters in systems requiring precise output voltages, especially at high output currents.

### SUMMARY

According to an example, a circuit includes a first switching device having a first terminal coupled to a first power supply terminal and a control terminal; a second switching device having a first terminal coupled to a second terminal of the first switching device and a second terminal coupled to a second power supply terminal; a first op amp having a non-inverting input coupled to a load terminal; a first resistor having a first terminal coupled to an output of the first op amp and a second terminal coupled to an inverting input of the first op amp; a second resistor having a first terminal coupled to the second terminal of the first switching device and a second terminal coupled to the inverting input of the first op amp; a first capacitor having a first terminal coupled to the output of the first op amp and a second terminal coupled to the inverting input of the first op amp; and a third resistor having a first terminal coupled to output of the first op amp and a second terminal coupled to the load terminal.

According to another example, a voltage converter circuit includes a switched-mode voltage converter that can switch a current at an output terminal responsive to a voltage at a load terminal, and a ripple cancellation circuit, having inputs coupled to the output terminal and the load terminal, and an output coupled to the output terminal. The ripple cancellation circuit outputs a cancellation current corresponding to an integration of a difference between the voltage at the load terminal and a voltage at the output terminal.

According to another example, a circuit includes a linear power amplifier, a voltage converter, and a control loop circuit. The voltage converter includes a first op amp having a non-inverting input coupled to a load terminal; a first resistor having a first terminal coupled to an output of the first op amp and a second terminal coupled to an inverting input of the first op amp; a second resistor having a first terminal coupled to the voltage converter output and a second terminal coupled to the inverting input of the first op amp; a first capacitor having a first terminal coupled to the output of the first op amp and a second terminal coupled to the inverting input of the first op amp; and a third resistor having a first terminal coupled to output of the first op amp and a second terminal coupled to the load terminal.

Example technical advantages enabled by one or more of these examples include significant reduction in the output ripple from switched-mode voltage converters, without requiring increases in the sizes of a power inductor or filter capacitor, or an increase in the switching frequency. The described examples can also be implemented on-chip with the voltage converter circuitry.

Other example technical advantages enabled by this description are apparent to those of ordinary skill in the art having reference to the following specification together with its drawings.

### BRIEF DESCRIPTION OF THE DRAWINGS

FIG. 1 is an electrical diagram, in block and schematic form, of an example switched-mode DC-DC voltage converter.

FIG. 2A is an electrical diagram, in schematic form, illustrating ripple current in a switched-mode DC-DC voltage converter.

FIG. 2B is an electrical diagram, in schematic form, illustrating cancellation of ripple current in the example switched-mode DC-DC voltage converter of FIG. 1.

FIG. 3 is an electrical diagram, in schematic form, of example ripple cancellation circuit in the voltage converter of FIG. 1.

FIG. 4 is an electrical diagram, in schematic form, of an example operational amplifier (op amp) in the ripple cancellation circuit of FIG. 3.

FIG. 5 is an electrical diagram, in schematic form, of another example ripple cancellation circuit in the voltage converter of FIG. 1.

FIG. 6 is an electrical diagram, in schematic form, of another example ripple cancellation circuit in the voltage converter of FIG. 1.

FIG. 7 is a waveform diagram illustrating an example of the operation of the voltage converter of FIG. 1 including the ripple cancellation circuit of FIG. 6.

FIG. 8 is an electrical diagram, in schematic form, of an example multi-phase switched-mode DC-DC voltage converter including an example ripple cancellation circuit.

FIG. 9 is an electrical diagram, in block form, of an example device power supply including the voltage converter of FIG. 1.

FIG. 10 is a flow diagram illustrating an example method of cancelling ripple in a switched-mode DC-DC voltage converter.

The same reference numbers or other reference designators are used in the drawings to illustrate the same or similar (in function and/or structure) features.

### DETAILED DESCRIPTION

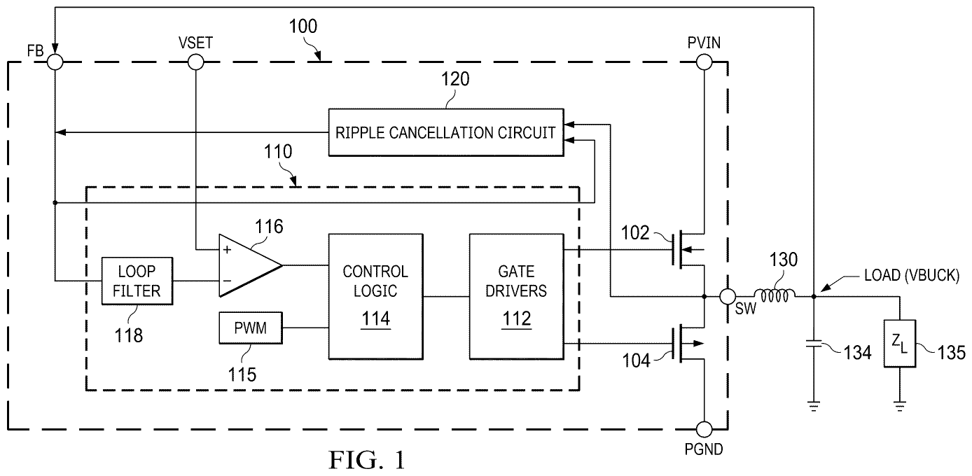

FIG. 1 illustrates an example switched-mode DC-DC voltage converter 100. Voltage converter 100 includes switching devices 102, 104, controller circuitry 110, and ripple cancellation circuit 120. Controller circuitry 110 includes gate drivers 112, control logic 114, pulse-width-modulation (PWM) circuit 115, error amplifier 116, and loop filter 118. In the example of FIG. 1, voltage converter 100 is implemented in combination with inductor 130, filter capacitor 134, and load 135.

In the example of FIG. 1, switching device 102 is implemented as a p-channel metal-oxide semiconductor (PMOS) transistor having a terminal (e.g., its source) coupled to power supply terminal PVIN, and another terminal (e.g., its drain) coupled to terminal SW of voltage converter 100. Switching device 104 is implemented as an n-channel metal-oxide semiconductor (NMOS) transistor having a terminal (e.g., its source) coupled to power supply terminal PGND, and another terminal (e.g., its drain) coupled to switching device 102 (e.g., its drain) at voltage converter terminal SW. In unipolar implementations, voltage converter 100 may be powered from a positive supply voltage at power supply terminal PVIN, with a common potential (e.g., system or circuit ground) at power supply terminal PGND. In bipolar implementations, voltage converter 100 may be powered from a positive supply voltage at power supply terminal PVIN and a negative voltage (e.g., relative to system or circuit ground) at power supply terminal PGND. Switching devices 102 and 104 each have a control terminal (e.g., a gate) coupled to corresponding outputs of gate drivers 112.

Alternatively to the implementation of switching devices 102 and 104 as a PMOS transistor and an NMOS transistor as shown in FIG. 1, one of switching devices 102 and 104 is implemented as a diode. For example, switching device 104 is replaced by a diode with its cathode at terminal SW and its anode at power supply terminal PGND. In such an implementation, only switching device 102 will have a control terminal (e.g., gate) coupled to an output of gate drivers 112.

Gate drivers 112 drive the control terminals of switching devices 102 and 104, in this example, in response to control signals received from control logic 114. Control logic 114 in this example has an input coupled to pulse-width-modulated (PWM) circuit 115. In an example, PWM circuit 115 generates a periodic signal, such as a sawtooth or ramp signal, at a selected switching frequency. Control logic 114 has another input coupled to the output of error amplifier 116. Error amplifier 116 has one input coupled to voltage converter terminal VSET. Loop filter 118 has an input coupled to feedback terminal FB, and an output coupled to a second input of error amplifier 116.

Feedback terminal FB in this example is coupled to terminal LOAD at load 135. Terminal VSET in this example receives a signal corresponding to a selected output voltage (e.g., setpoint voltage) at load 135. Alternatively, the setpoint voltage is stored in a memory location or register in voltage converter 100, for example as loaded from a data interface. In any case, error amplifier 116 generates an output signal corresponding to a difference between the voltage at terminal LOAD, as filtered by loop filter 118, and the setpoint voltage (e.g., at terminal VSET). The output signal from error amplifier 116 can determine the duty cycle at which switching devices 102 and 104 are turned on within each cycle of the sawtooth periodic waveform from PWM circuit 115.

Alternatively or additionally (e.g., in response to a mode select input), control logic 114 controls gate drivers 112 to turn switching devices 102 and 104 on and off according to a pulse frequency modulation (PFM) in which the on and off pulses are of constant width but varying in frequency in response to the output of error amplifier 116.

As shown in FIG. 1, inductor 130 has one terminal coupled to terminal SW, and another terminal coupled to one terminal of filter capacitor 134 at terminal LOAD. Filter capacitor 134 has a second terminal coupled to a common terminal (e.g., at circuit or system ground). In system use, load 135 is coupled to terminal LOAD, presenting an impedance Z_{L}.

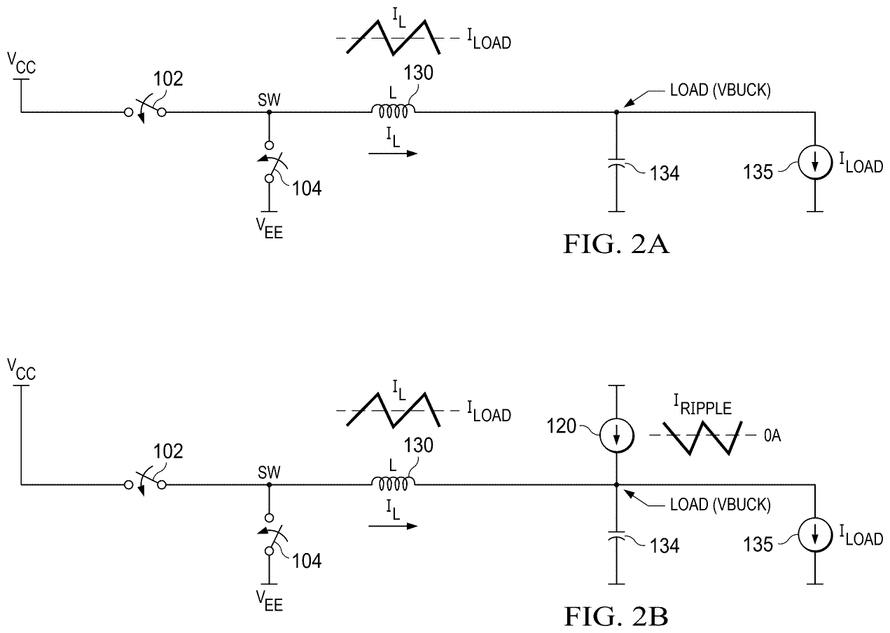

FIG. 2A illustrates the general operation of switched-mode step-down (“buck”) voltage converter 100. In this generalized illustration, switching devices 102 and 104 receive power supply voltages V_{CC} and V_{EE}, respectively. In this example, power supply voltage V_{CC} is higher (e.g., above a ground level) than power supply voltage V_{EE} (e.g., below a ground level).

In a first phase within each of a sequence of clock cycles, switching device 102 is closed while switching device 104 is open, applying voltage V_{CC} to inductor 130 at terminal SW. Inductor 130 conducts an increasing current I_{L} in the direction from terminal SW to load 135. The rate of change of current I_{L} depends on the inductance of inductor 130 and the voltage differential between terminals SW and LOAD. In a second phase, switching device 104 is closed while switching device 102 is open, applying negative voltage V_{EE} to inductor 130 at terminal SW. This causes current I_{L} through inductor 130 to decrease, at a rate of change depending again on the inductance of inductor 130 and the voltage differential between terminals SW and LOAD. This two-phase operation continues at the switching frequency of the voltage converter. The resulting voltage at load 135 (e.g., at terminal LOAD) depends on the relative duty cycles of switching devices 102 and 104.

For the alternative case in which, for example, switching device 104 is implemented as a diode, switching device 104 will be reverse-biased when switching device 102 is opened, because the inductor current I_{L} cannot change instantaneously, which forces a negative voltage at terminal SW.

In a steady state condition, the switched mode operation of switching devices 102 and 104, which causes the inductor current I_{L} to increase and decrease within each cycle, results in a “ripple” around the average load current I_{load} delivered to load 135, as shown in FIG. 1A. The magnitude of this ripple current depends on the input voltages (e.g., V_{CC} and V_{EE}), the output voltage VBUCK at terminal LOAD, the size of inductor 130, the relative duty cycles of switching devices 102 and 104, and the switching frequency. For example, the peak-to-peak amplitude ΔI_{L} of the ripple current is expressed as:

$$Δ {I}_{L} = \frac{{V}_{CC} - VBUCK}{L} \cdot D \cdot T = \frac{{V}_{EE} - VBUCK}{L} \cdot ( 1 - D ) \cdot T \qquad ( 1 )$$

where D is the duty cycle of switching device 102 and T is the switching period. This ripple current is integrated into capacitor 134, and results in ripple in the output voltage at terminal LOAD:

$$Δ VBUCK = T \cdot \frac{Δ {I}_{L}}{8 \cdot {C}_{134}} \qquad ( 2 )$$

where C₁₃₄ is the capacitance of filter capacitor 134, and assuming zero effective series resistance (ESR) of filter capacitor 134. A non-zero ESR of filter capacitor 134 further exacerbates the output voltage ripple.

Switched-mode voltage converters consume substantially less power than alternative power converter topologies such as linear power amplifiers. As such, switched-mode converters are attractive for use in system applications in which power consumption or heat removal is a significant concern. An example of such an application is modern automated test equipment, in which a power converter for each of an ever-increasing number of channels. However, such equipment also requires the power converter to deliver high currents (e.g., on the order of amperes) at precise DC voltages. The inherent ripple of switched-mode power converters, as described above relative to FIG. 2A, has previously favored the use of linear power amplifiers in such precision applications, despite the high power consumption.

The ripple at the output of the switched-mode voltage converter of FIG. 2A can be reduced by increasing the inductance of inductor 130 and increasing the capacitance of filter capacitor 134, at a cost of higher component cost, increased circuit board space, and poorer load transient performance. Ripple can also be reduced by increasing the switching frequency of the switched-mode voltage converter, but at a cost of higher switching losses. Higher switching frequencies also reduce the maximum duty cycle due to the fraction of each cycle consumed by rise and fall times, thus limiting the achievable output dynamic range.

Another approach to reducing output ripple is to provide a multi-phase converter, in which load current is driven through multiple inductors 130, coupled in parallel and operated in a time-interleaved fashion. The parallel inductors effectively appear to the load as a small overall inductance, reducing load transients. Multi-phase converters require substantially larger circuit board area, however, and further require a separate external terminal (e.g., pin) for each phase.

It is within this context that the described examples arise.

FIG. 2B illustrates the theory of operation of the example voltage converters described in this specification. The switched-mode step-down voltage converter shown in FIG. 2B corresponds to that of FIG. 2A, with the addition of ripple cancellation current source 120 sourcing a current Iᵣᵢₚₚₗₑ into terminal LOAD. In this architecture, ripple cancellation current Iᵣᵢₚₚₗₑ is in phase opposition with the ripple in inductor current I_{L}, at the same peak-to-peak amplitude. Ideally, ripple cancellation current Iᵣᵢₚₚₗₑ has an average (e.g., DC) value of ˜0 A, to avoid additional DC power consumption. Because inductor current I_{L} and ripple cancellation current Iᵣᵢₚₚₗₑ are summed at terminal LOAD, the resulting ripple in the output voltage at load 135 is much reduced.

Referring to FIG. 1, ripple cancellation circuit 120 is provided in example voltage converter 100 to provide such a ripple cancellation current Iᵣᵢₚₚₗₑ. In this example, ripple cancellation circuit 120 has an input coupled to feedback terminal FB, and an input coupled to terminal SW. Ripple cancellation circuit 120 has an output coupled to feedback terminal FB, which is coupled in this example to load 35 at terminal LOAD.

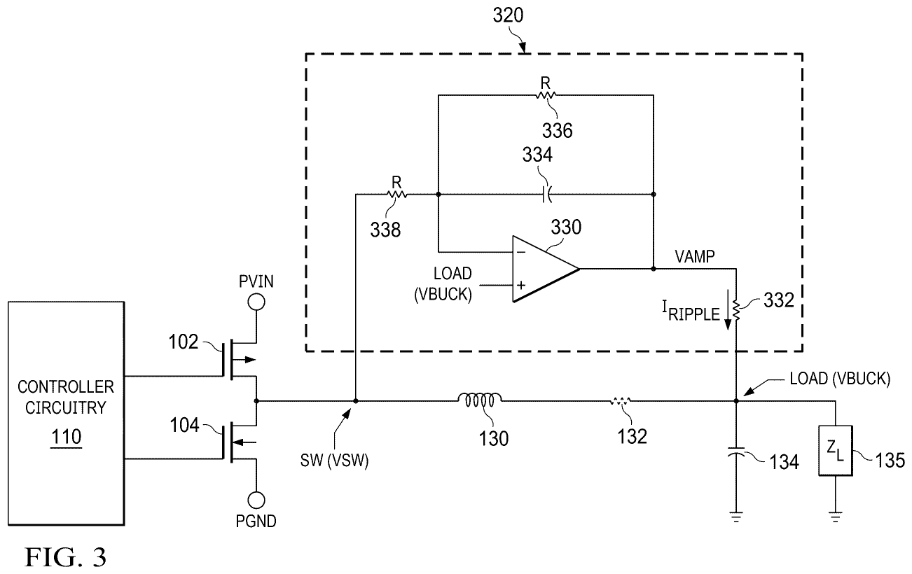

FIG. 3 illustrates ripple cancellation circuit 320, as an example of ripple cancellation circuit 120 of FIG. 1, in combination with switching devices 102, 104, controller circuitry 110, inductor 130 (with effective series resistance 132), filter capacitor 134, and load 135. Ripple cancellation circuit 320 in this example includes operational amplifier (op amp) 330, resistors 332, 336, 338, and capacitor 334.

Switching devices 102, 104, controller circuitry 110, inductor 130 (with effective series resistance 132), filter capacitor 134, and load 135 are connected within voltage converter 100 in the manner described above in connection with FIG. 1. FIG. 3 illustrates the parasitic resistance, or effective series resistance (ESR), of inductor 130 in the form of resistor 132 coupled in series with inductor 130 between terminal SW and terminal LOAD.

In example ripple cancellation circuit 320 of FIG. 3, resistor 338 has one terminal coupled to terminal SW, and a second terminal coupled to the inverting input of op amp 330. The non-inverting input of op amp 330 is coupled to terminal LOAD at load 135. In the implementation of FIG. 1, this non-inverting input of op amp 330 may be coupled to feedback terminal FB, which in turn is coupled to terminal LOAD. Voltage VBUCK is thus received at the non-inverting input of op amp 330. Resistor 336 has one terminal coupled to the inverting input of op amp 330 and another terminal coupled to the output of op amp 330. Similarly, capacitor 334 has one terminal coupled to the inverting input of op amp 330 and another terminal coupled to the output of op amp 330, in parallel with resistor 336. In this example, resistors 336 and 338 have the same resistance R. As such, op amp 330 is implemented as a unity gain integrator. Resistor 332 has one terminal coupled to the output of op amp 330 and another terminal coupled to terminal LOAD.

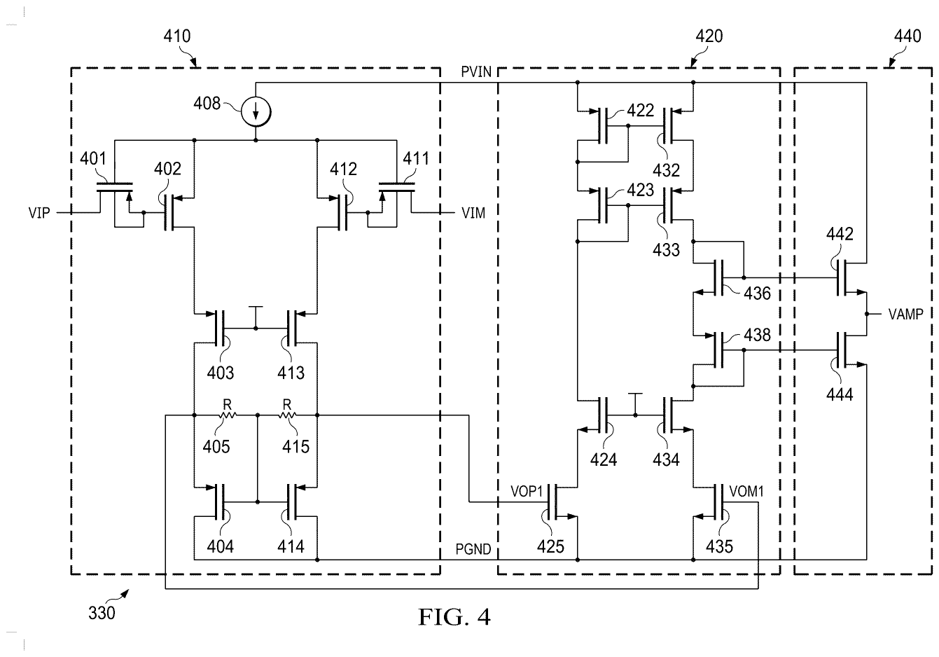

FIG. 4 illustrates an example of op amp 330 in further detail. Op amp 330 in this example includes differential input stage 410, current mirror stage 420, and output stage 440. Differential input stage 410 includes PMOS transistors 401, 402, 403, 411, 412, and 413, NMOS transistors 404 and 414, and resistors 405 and 415. Current mirror stage 420 includes PMOS transistors 422, 423, 432, 433, and 438, and NMOS transistors 424, 425, 434, and 435. Output stage includes PMOS transistors 444 and 442.

In high voltage implementations of voltage converter 100, for example with input voltages up to on the order of +/−10V, some of the transistors of op amp 330 are constructed according to high voltage technologies. For example, referring to FIG. 4, PMOS transistors 401, 403, 411, 413, 423, 424, 433, 434, and 444 may be constructed as drain-extended (DE) MOS transistors, and NMOS transistors 436 and 442 are constructed as lightly-doped-drain (LD) MOS transistors. The other transistors are constructed as “low voltage” transistors, for example with similar construction as logic circuit transistors in the same integrated circuit as voltage converter 100.

In op amp 330 according to the example of FIG. 4, differential input stage 410 has inputs VIP, VIM, which correspond to the non-inverting and inverting inputs of op amp 330 in the arrangement of FIG. 3. Differential input stage 410 has outputs VOP1, VOM1, which present a differential output voltage to corresponding inputs of current mirror stage 420. Current mirror stage 420 has two outputs, one coupled to the gate of NMOS transistor 442 of output stage 440, and the other coupled to the gate of PMOS transistor 444 of output stage 440. Output stage 440 has a single-ended output in this example, at which voltage VAMP appears during operation.

In the operation of ripple cancellation circuit 320 in FIG. 3, op amp 330 receives voltage VBUCK from terminal LOAD at its non-inverting input, and a voltage VSW from node SW at its inverting input. Considering op amp 330 as a unity gain integrator, a voltage VAMP at the output of op amp 330 can be expressed as:

$$VAMP = \frac{- ( VSW - VBUCK )}{( 1 + RCs )} + VBUCK \qquad ( 3 )$$

where R is the resistance of each of resistors 336, 338, C is the capacitance of capacitor 334, and s is the Laplace operator. Op amp 330 outputs a current Iᵣᵢₚₚₗₑ that can be expressed as:

$${I}_{ripple} = \frac{VAMP - VBUCK}{{R}_{332}} = \frac{- ( VSW - VBUCK )}{1 + RCs} \cdot \frac{1}{{R}_{332}} \qquad ( 4 a )$$

where R₃₃₂ is the resistance of resistor 332. The voltage difference −(VSW−VBUCK) is also the voltage across inductor 130. Accordingly, current Iᵣᵢₚₚₗₑ can also be expressed as:

$${I}_{ripple} = \frac{- {I}_{L} ( s ) \cdot ( Ls + {ESR}_{132} )}{1 + RCs} \cdot \frac{1}{{R}_{332}} \qquad ( 4 b )$$

where ESR₁₃₂ is the parasitic series resistance of inductor 130, illustrated in FIG. 3 as resistor 132.

One can estimate the high frequency AC component of current Iᵣᵢₚₚₗₑ as:

$${I}_{ripple} ( ac ) ≅ \frac{- {I}_{L} ( ac )}{RC} \cdot \frac{L}{{R}_{332}}$$

Ideally, this AC current component current Iᵣᵢₚₚₗₑ(ac) provided by op amp 330 is equal to the negative of the AC inductor current component I_{L}(ac). One example approach to optimizing this ripple cancellation current is to select an inductance L for inductor 130 that matches the product R·C·R₃₃₂ in equation (5).

In ripple cancellation circuit 320 of FIG. 3, a larger resistance value R₃₃₂ results in a larger peak-to-peak amplitude of the voltage VAMP, which increases the slew rate requirement of op amp 330. On the other hand, this larger resistance value R₃₃₂ also serves to better isolate op amp 330 from the effects of filter capacitor 334, which eases the stability requirements of op amp 330. In practice, for example, a resistance value R₃₃₂ of 1 to 3Ω for resistor 332 has been used, with the capacitance C of capacitor 334 and resistance R of each of resistors 336 and 338 chosen according to equation (5) to match the inductance L of inductor 130 for the particular application of voltage converter 100.

Accordingly, ripple cancellation circuit 320 provides a ripple cancellation current Iᵣᵢₚₚₗₑ to terminal LOAD that is in phase opposition with the ripple current I_{L}(ac) generated by the switching of current through inductor 130. Matching of the peak-to-peak amplitude of ripple cancellation current Iᵣᵢₚₚₗₑ to the ripple current I_{L}(ac) can be attained by selection of component sizes (e.g., resistance and capacitance values) in ripple cancellation circuit 320, or of inductor 130.

In some implementations, ripple cancellation current Iᵣᵢₚₚₗₑ includes a non-zero DC component:

$${I}_{ripple} ( dc ) = \frac{- ( {I}_{L} ( dc ) \cdot {ESR}_{132} )}{{R}_{332}} = \frac{- ( {I}_{load} \cdot {ESR}_{132} )}{{R}_{332}} \qquad ( 6 )$$

where I_{load} is the average load current conducted by load 135 (e.g., the DC inductor current component I_{L}(dc)). The non-zero DC ripple current component Iᵣᵢₚₚₗₑ(dc) output by op amp 330 and conducted through resistor 332 causes power dissipation in ripple cancellation circuit 320, and can be significant in some implementations.

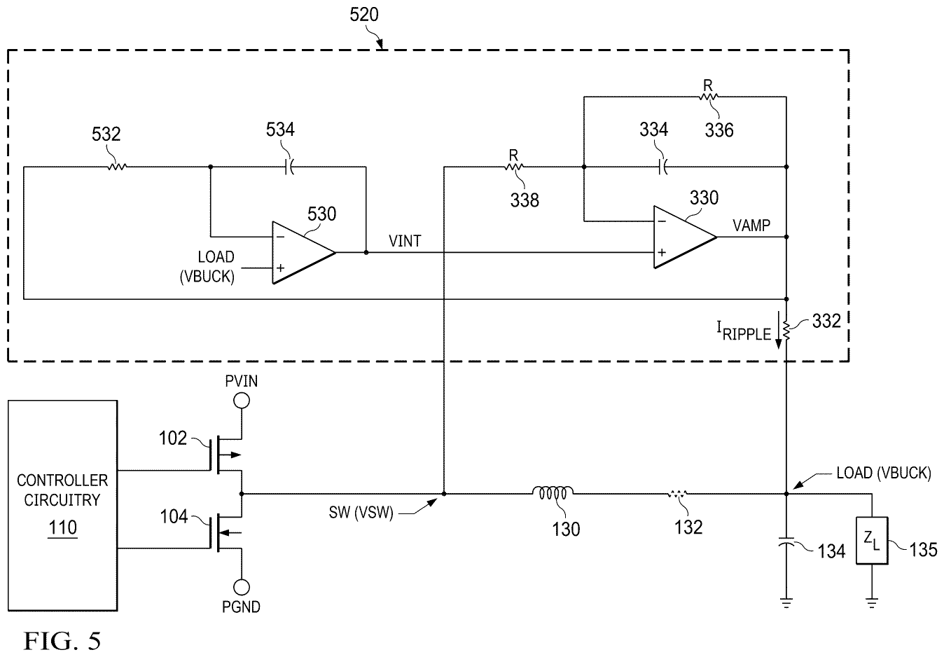

FIG. 5 illustrates ripple cancellation circuit 520, as another example of ripple cancellation circuit 120 of FIG. 1, in combination with switching devices 102, 104, controller circuitry 110, inductor 130 (with ESR 132), filter capacitor 134, and load 135. Similarly as ripple cancellation circuit 320 of FIG. 3, ripple cancellation circuit 520 includes op amp 330, resistors 332, 336, 338, and capacitor 334. Ripple cancellation circuit 520 in this example further includes op amp 530, capacitor 534, and resistor 532.

Op amp 330, resistors 336 and 338, and capacitor 334 are arranged as a unity gain integrator in the same manner as described above relative to FIG. 3. Resistor 332 also similarly has one terminal coupled to the output of op amp 330 and a second terminal coupled to terminal LOAD. The inverting input of op amp 330 is coupled to terminal SW through resistor 338, similarly as in ripple cancellation circuit 320. In this example, the non-inverting input of op amp 330 is not coupled directly to terminal LOAD, but is instead coupled to the output of op amp 530.

In an example, op amp 530 in ripple cancellation circuit 520 is constructed similarly as op amp 330 described above relative to FIG. 4. Op amp 530 has a non-inverting input coupled to terminal LOAD. Capacitor 534 has one terminal coupled to the output of op amp 530, and a second terminal coupled to the inverting input of op amp 530. Resistor 532 has one terminal coupled to the non-inverting input of op amp 530, and a second terminal coupled to the output of op amp 530.

Op amp 530 and its associated components provide a feedback loop to reduce the DC component Iᵣᵢₚₚₗₑ(dc) of the ripple cancellation current provided by ripple cancellation circuit 520. In operation, op amp 530 effectively integrates a difference between voltage VAMP at the output of op amp 330 and the voltage VBUCK at terminal LOAD. Op amp 530 outputs a voltage VINT corresponding to this integration:

$$VINT = VBUCK \cdot ( 1 + \frac{1}{s \cdot {R}_{532} \cdot {C}_{534}} ) - VAMP \cdot ( \frac{1}{s \cdot {R}_{532} \cdot {C}_{534}} ) \qquad ( 7 a )$$

where R₅₃₂ is the resistance of resistor 532 and C₅₃₄ is the capacitance of capacitor 534. Rearranging this equation (8a) leads to this expression for voltage VINT:

$$VINT = ( VBUCK - VAMP ) \cdot ( 1 + \frac{1}{s \cdot {R}_{532} \cdot {C}_{534}} ) + VBUCK \qquad ( 7 b )$$

Following equation (7b), at DC (s=0), the integration provided by op amp 530 enables VAMP=VBUCK, resulting in no DC ripple cancellation current (e.g., Iᵣᵢₚₚₗₑ(dc)=0). The feedback loop including op amp 530 attains this condition by controlling the voltage VINT at the non-inverting input of op amp 330 to cause its output voltage VAMP to match voltage VBUCK at terminal LOAD.

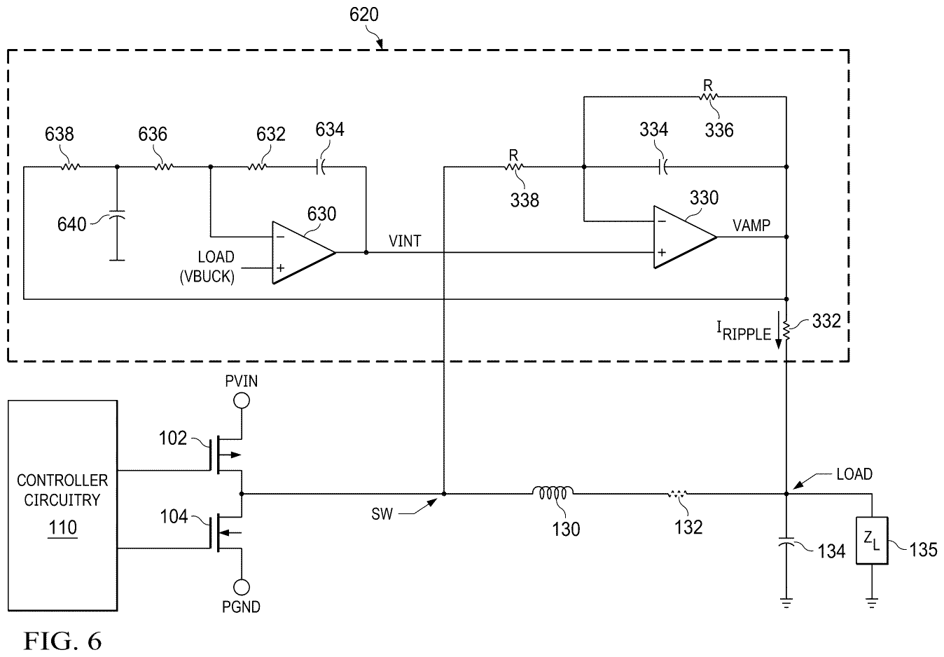

FIG. 6 illustrates ripple cancellation circuit 620, as another example of ripple cancellation circuit 120 of FIG. 1, in combination with switching devices 102, 104, controller circuitry 110, inductor 130 (with ESR 132), filter capacitor 134, and load 135. Similarly as ripple cancellation circuits 320 and 520 of FIGS. 3 and 5, respectively, ripple cancellation circuit 620 again includes op amp 330, resistors 332, 336, 338, and capacitor 334. Ripple cancellation circuit 620 further includes op amp 630, capacitors 634 and 640, and resistors 632, 636, and 638.

Op amp 330, resistors 336 and 338, and capacitor 334 are again arranged as a unity gain integrator in the same manner as described above relative to FIG. 3. Resistor 332 also similarly has one terminal coupled to the output of op amp 330 and a second terminal coupled to terminal LOAD. The inverting input of op amp 330 is coupled to terminal SW through resistor 338, similarly as in ripple cancellation circuit 320. In this example, the non-inverting input of op amp 330 is not coupled directly to terminal LOAD, but is instead coupled to the output of op amp 630.

In an example, op amp 630 in ripple cancellation circuit 620 is constructed similarly as op amp 330 described above relative to FIG. 4. Op amp 630 has a non-inverting input coupled to terminal LOAD. Resistor 632 has one terminal coupled to the inverting input of op amp 630, and another terminal coupled to one terminal of capacitor 634. Capacitor 634 has another terminal coupled to the output of op amp 530. As such, resistor 632 and capacitor 634 are coupled in series to provide a feedback network between the output of op amp 630 and its inverting input.

Resistor 636 has one terminal coupled to the inverting input of op amp 630, and another terminal coupled to one terminal of resistor 638 and one terminal of capacitor 640. Resistor 638 has another terminal coupled to the output of op amp 330, and capacitor 640 has another terminal coupled to a power supply or a common terminal.

Similarly as in the example of FIG. 5, op amp 630 and its associated components provide a feedback loop to reduce the DC ripple cancellation current component Iᵣᵢₚₚₗₑ(dc). The stability of this feedback loop is improved in ripple cancellation circuit 620 according to this example. In particular, the insertion of resistor 632 in series with capacitor 634 in the feedback path of op amp 630 adds a low frequency zero to the transfer characteristic of ripple cancellation circuit 620, helping to stabilize the loop.

However, this series resistor 632 can also increase gain at the ripple frequency, which can distort the voltage waveform at the output of op amp 330 and thus degrade ripple cancellation current Iᵣᵢₚₚₗₑ. Resistors 636 and 638, and capacitor 640 filter the voltage VAMP as it is fed back to the inverting input of op amp 630 from the output of op amp 330. In operation, the filter of resistors 636 and 638 and capacitor 640 reduces ripple in voltage VINT output by op amp 630, improving the ripple cancellation at terminal LOAD as a result. The component values of resistors 636 and 638 and capacitor 640 can be selected to keep the cutoff frequency (e.g., −3 dB frequency) outside of the loop bandwidth, so as not to degrade the phase margin of this feedback loop.

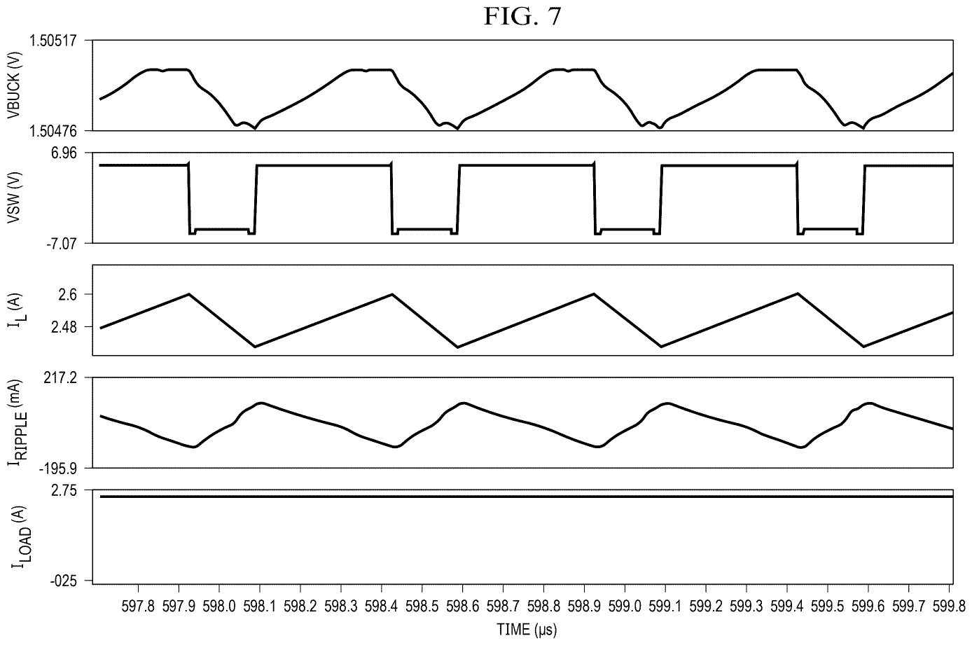

FIG. 7 illustrates the results of a simulation of an example of voltage converter 100 including ripple cancellation circuit 630. In this example, an output voltage VBUCK=1V at an output current of up to 2.5 A into load 135 is generated from a power supply voltage V_{CC}=5V and a power supply voltage V_{EE}=−5V (e.g., an input voltage of 10V), using a switching frequency of 2 MHz. Inductor 130 has an inductance L=5.6 μH, and filter capacitor 134 has a capacitance C of 10 μF. With these parameters, FIG. 7 illustrates voltage VBUCK at terminal LOAD of voltage converter 100 ramping up and down at the switching frequency in response to the turning on and off of switching devices 102 and 104. For example, when switching device 102 is on (and switching device 104 is off), voltage VSW is near power supply voltage V_{CC}, during which time voltage VBUCK and inductor current I_{L} increase. Conversely, when switching device 104 is on (and switching device 102 is off), voltage VSW is near the negative power supply voltage V_{EE}, during which time voltage VBUCK and inductor current I_{L} decrease. The peak-to-peak ripple in inductor current I_{L} is about 200 mA in this example, at an average current of about 2.5 A.

In this simulated example of ripple cancellation circuit 630, resistors 336, 338 each have a resistance of 225 kΩ, and capacitor 334 has a capacitance of 25 pF, resulting in the integrator of op amp 330 having a pole at about 28 kHz. Resistors 636 and 638 each have a resistance of 250 kΩ, resistor 632 has a resistance of 500 kΩ, and capacitor 634 has a capacitance of 25 pF. As a result, the controller circuit of op amp 630 has a unity gain frequency at about 45 kHz with a zero in its transfer function at about 30 kHz, and a phase margin of about 75°. In simulation, this construction of ripple cancellation circuit 630 provided a ripple cancellation current Iᵣᵢₚₚₗₑ of an amplitude closely matching, but in phase opposition to, inductor current I_{L}. Quantitatively, according to the simulation results shown in FIG. 7, a steady current I_{load} of about 2.5 A is delivered to load 135, at a ripple current amplitude within 10 mA (peak-to-peak), resulting in a ripple in the output voltage of less than 100 μV.

The described examples thus enable significant (e.g., on the order of 10×) reduction in output ripple in switched-mode buck converters. This ripple reduction can be attained using a relatively small power inductor, which in turn enables higher maximum output current, improved load transient performance, and improved efficiency due to lower inductor ESR. The example voltage converters can also attain this performance at lower switching frequencies such as 2 MHz, thus avoiding the increased switching losses and limited maximum duty cycle of higher switching frequencies. The ripple cancellation circuits according to these examples are implemented on-chip with unipolar or bipolar voltage converter circuitry to provide closed-loop control of the DC-DC conversion.

In addition, the described examples enable this reduction in output ripple in single-phase voltage converter circuits, avoiding the need for multi-phase voltage conversion in some implementations. However, ripple cancellation according to the described examples can be applied also in a multi-phase context, for example to attain ultra-low output ripple.

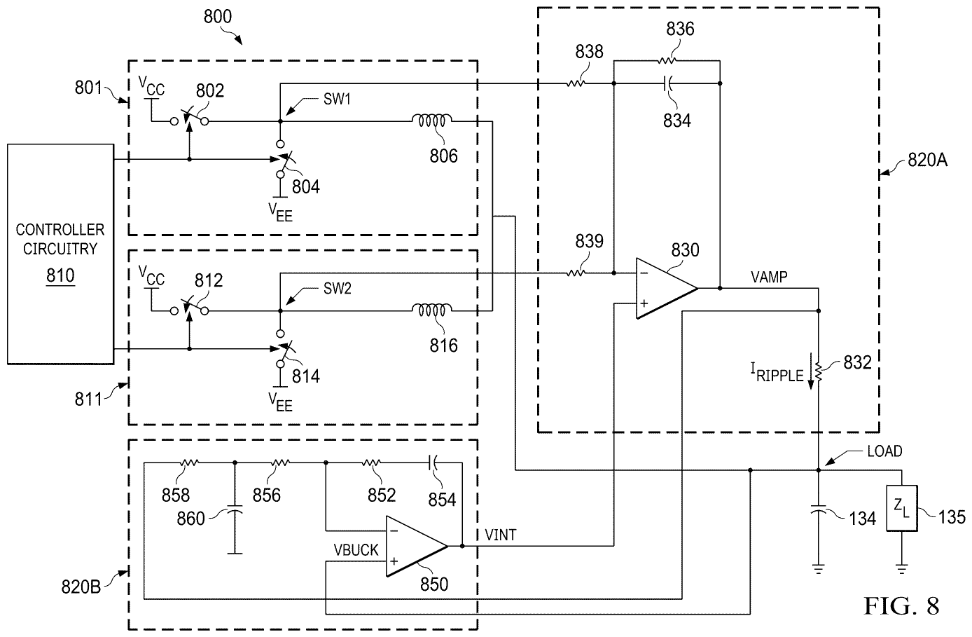

FIG. 8 illustrates an example multi-phase voltage converter 800, as implemented with load 135 and filter capacitor 134. Voltage converter 800 includes controller circuitry 100, switching stages 801 and 811, and ripple cancellation circuit 820 (referring to portions 820A and 820B collectively). Switching stage 801 includes switching devices 802, 804, and inductor 806. Switching stage 811 includes switching devices 812, 814, and inductor 816. Ripple cancellation circuit portion 820A includes op amp 830, resistors 832, 836, 838, and 839, and capacitor 834. Ripple cancellation circuit portion 820B includes op amp 850, resistors 852, 856, and 858, and capacitors 854 and 860.

Switching devices 802 and 804 in switching stage 801 correspond to transistors 102, 104, respectively, of FIG. 1, as do switching devices 812 and 814, respectively, in switching stage 802. In switching stage 801, switching devices 802 and 804 have terminals coupled together and to one terminal of inductor 806 at terminal SW1. Inductor 806 has another terminal coupled to load 135 and filter capacitor 134, at terminal LOAD. Similarly, in switching stage 811, switching devices 812 and 814 have terminals coupled together and to one terminal of inductor 816 at terminal SW2. Inductor 816 also has another terminal coupled to load 135 and filter capacitor 134, at terminal LOAD.

In ripple cancellation circuit portion 820A according to this example, resistor 838 has one terminal coupled to terminal SW1, and a second terminal coupled to the inverting input of op amp 830. Resistor 839 has one terminal coupled to terminal SW2, and a second terminal also coupled to the inverting input of op amp 830. Resistor 836 has one terminal coupled to the inverting input of op amp 830 and another terminal coupled to the output of op amp 830. Capacitor 834 has one terminal coupled to the inverting input of op amp 830 and another terminal coupled to the output of op amp 830, in parallel with resistor 836. In this example, resistors 836, 838, and 839 have the same resistance as one another, configuring op amp 830 as a unity gain integrator. Resistor 832 has one terminal coupled to the output of op amp 830 and another terminal coupled to terminal LOAD.

Ripple cancellation circuit portion 820B provides a feedback loop to op amp 850. Similarly as described above in connection with ripple cancellation circuit 620 of FIG. 6, op amp 850 has a non-inverting input coupled to terminal LOAD. Resistor 852 has one terminal coupled to the inverting input of op amp 850, and another terminal coupled to one terminal of capacitor 854. Capacitor 854 has another terminal coupled to the output of op amp 850, coupling resistor 852 and capacitor 854 in series between the output of op amp 850 and its inverting input. Resistor 856 has one terminal coupled to the inverting input of op amp 850, and another terminal coupled to one terminal of resistor 858 and one terminal of capacitor 860. Capacitor 860 has another terminal coupled to a power supply or a common terminal. Resistor 858 has another terminal coupled to the output of op amp 830 in ripple cancellation circuit portion 820A. As described above, resistors 856 and 858 together with capacitor 860 filter the voltage VAMP as it is fed back to the inverting input of op amp 850 from the output of op amp 850. This filter reduces ripple in the voltage output by op amp 630, which improves the ripple cancellation at terminal LOAD as a result.

In this multi-phase voltage controller 800, controller circuitry 810 controls switching devices 802 and 804 in switching stage 801 and switching devices 812 and 814 in switching stage 802 in separate non-overlapping phases. For example, within a first phase, controller circuitry 810 controls switching devices 802 and 804 to apply power supply voltage V_{CC} and power supply voltage V_{EE}, respectively, to inductor 806 at terminal SW1. During this first phase, controller circuitry 810 turns off switching devices 812 and 814 in switching stage 802. Conversely, in a second phase, controller circuitry 810 controls switching devices 812 and 814 to apply power supply voltage V_{CC} and power supply voltage V_{EE}, respectively, to inductor 816 at terminal SW2, while turning off switching devices 802 and 804 in switching stage 802.

The combination of this multi-phase operation of voltage controller 800 with ripple cancellation circuit 820 can provide even further reduction in the ripple at load 135, as may be attractive in certain system implementations. In addition, the number of switching stages, and thus the number of phases, may be increased beyond the two stages 801, 802 of voltage controller 800 to further reduce output ripple.

The advantages provided by the described examples can enable the use of switched-mode voltage converters to be implemented in certain demanding system applications. One example of a demanding application for voltage converters is a device power supply (DPS) in automated test equipment (ATE), such as used in the testing of integrated circuits.

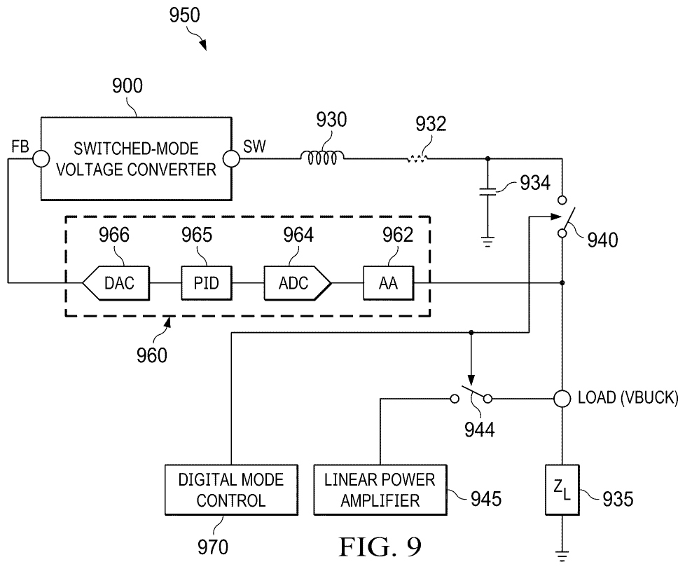

FIG. 9 illustrates an example device power supply (DPS) 950 for supplying DC voltage and current to load 935. DPS 950 includes switched-mode voltage converter 900, inductor 930 (with ESR represented by resistor 932), filter capacitor 934, switches 940 and 944, linear power amplifier 945, digital control loop circuit 960, and digital mode control circuit 970. Digital control loop circuit 960 includes anti-aliasing filter 962, analog-to-digital converter (ADC) 964, proportional-integral-derivative (PID) controller 965, and digital-to-analog converter (DAC) 966.

As noted above, DPS 950 in this example includes both switched-mode voltage converter 900 and linear power amplifier 945. Voltage converter 900 has an output at terminal SW coupled to one terminal of power inductor 930 (with its ESR 932), which in turn has another terminal coupled to one terminal of switch 940. Switch 940 has another terminal coupled to load 935 at terminal LOAD. Linear power amplifier 945 has an output coupled to one terminal of switch 944, which in turn has another terminal coupled to load 935 at terminal LOAD. Switch 944 also has a control terminal coupled to an output of digital mode control circuit 970.

In the context of DPS 950 being implemented in ATE, load 935 corresponds to a device under test (DUT). In this example, digital mode control circuit 970 controls switches 940 and 944 to select either switched-mode voltage converter 900 or linear power amplifier 945 to drive load 935. This selection by digital mode control circuit 970 may be made in response to user inputs or under program control. For example, digital mode control circuit 970 selects linear power amplifier 945 to drive load 935 at lower current levels (e.g., from 1 μA to 100 mA), and select switched-mode voltage converter 900 to drive load 935 at higher current levels (e.g., from 100 mA to 2.5 A).

Switched-mode voltage converter 900 in this example corresponds to voltage converter 100 described above according to FIG. 1. As such, voltage converter 900 includes a ripple cancellation circuit 120, for example constructed as one of ripple cancellation circuits 320, 520, 620 described above, or as ripple cancellation circuit 820 in a multi-phase implementation.

DPS 950 in this example includes digital control loop circuit 960 for additional precision and accuracy in the DC voltage and current driven to load 935 by voltage converter 900. In this example, anti-aliasing filter 962 has an input coupled to terminal LOAD, and an output coupled to an input of DAC 964. DAC 964 converts the analog output of anti-aliasing filter 962 to a digital value, which it outputs to an input of PID controller 965. PID controller 965 conditions this digital signal, and outputs the result to DAC 966, which converts the signal-conditioned output of PID controller 965 to an analog signal. The output of DAC 966 is coupled to feedback terminal FB of voltage converter 900.

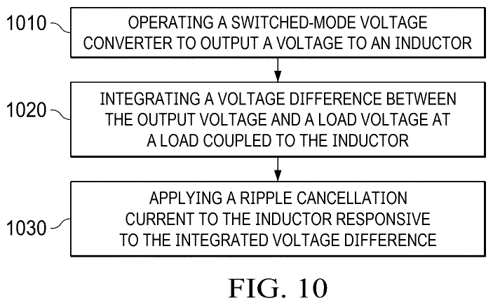

FIG. 10 illustrates an example of a generalized method of operating a voltage converter including a ripple cancellation circuit according to the examples described above. In process block 1010 of this example method, a switched-mode voltage converter is operated, for example by turning on and off switching devices 102 and 104 in voltage converter 100 of FIG. 1 to drive a switched voltage to one terminal of inductor 130, at terminal SW.

As shown in FIG. 1, ripple cancellation circuit 120 of voltage converter 100 has an input coupled to terminal SW and an input coupled to load 135 at terminal LOAD, at a second terminal of inductor 130. In process block 1020, ripple cancellation circuit 120 integrates a voltage difference between the output voltage at terminal SW and the load voltage at load 135 (terminal LOAD). As described above, this integration may be performed by a unity gain integrator op amp circuit. FIG. 3 illustrates an example of this unity gain integrator in its arrangement of op amp 330, resistors 336 and 338, and capacitor 334. As described above in connection with FIGS. 5 and 6, ripple cancellation circuit 120 may include a feedback loop adjusting the load voltage applied to the unity gain integrator.

In process block 1030, ripple cancellation circuit 120 applies a ripple cancellation current to the inductor, for example at terminal LOAD, responsive to the integrated voltage difference. This ripple cancellation current is in phase opposition to ripple in the output current from voltage converter 100, and thus serves to reduce the overall ripple at load 135. Selection of component values (capacitances and resistances) in ripple cancellation circuit 120, and of inductor 130, can provide an amplitude of this ripple cancellation current closely matching that of the ripple in the output current. Including a feedback loop in ripple cancellation circuit 120, as described above, can reduce the DC level of the ripple cancellation current applied in process block 1030.

As noted above, examples are described in this specification as implemented into switched-mode buck voltage converters, as such implementation can be advantageous in that context. An example of a DPS incorporating such a voltage converter, for example in addition to or replacing a linear power amplifier, is also described. However, aspects of the described example voltage converters may be beneficially applied in alternative applications and contexts. Accordingly, the above description is provided by way of example only, and does not limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means+/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some examples, certain elements are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. A circuit, comprising:
a first switching device, having a first terminal coupled to a first power supply terminal, a second terminal, and a control terminal;
a second switching device, having a first terminal coupled to the second terminal of the first switching device, and a second terminal coupled to a second power supply terminal;
a first op amp, having an inverting input, a non-inverting input coupled to a load terminal, and an output;
a first resistor, having a first terminal coupled to the output of the first op amp, and a second terminal coupled to the inverting input of the first op amp;
a second resistor, having a first terminal coupled to the second terminal of the first switching device and a second terminal coupled to the inverting input of the first op amp;
a first capacitor, having a first terminal coupled to the output of the first op amp, and a second terminal coupled to the inverting input of the first op amp; and
a third resistor, having a first terminal coupled to output of the first op amp, and a second terminal coupled to the load terminal.

2. The circuit of claim 1, further comprising:
an inductor, having a first terminal coupled to the second terminal of the first switching device, and a second terminal coupled to the load terminal; and
a second capacitor, having a first terminal coupled to load terminal and a second terminal coupled to a ground terminal.

3. The circuit of claim 1, further comprising:
a second op amp, having an inverting terminal, a non-inverting terminal coupled to the load terminal, and an output coupled to the non-inverting terminal of the first op amp;
a fourth resistor, having a first terminal coupled to the output of the first op amp, and a second terminal coupled to the inverting input of the second op amp; and
a second capacitor, having a first terminal coupled to the output of the second op amp, and a second terminal coupled to the inverting input of the second op amp.

4. The circuit of claim 1, further comprising:
a second op amp, having an inverting terminal, a non-inverting terminal coupled to the load terminal, and an output coupled to the non-inverting terminal of the first op amp;
a second capacitor, having a first terminal coupled to the output of the second op amp, and a second terminal coupled to the inverting input of the second op amp;
a fourth resistor, having a first terminal coupled to the output of the second op amp, and a second terminal coupled to the inverting input of the second op amp, the second capacitor and fourth resistor coupled in series;
a fifth resistor, having a first terminal coupled to the inverting input of the second op amp, and a second terminal;
a sixth resistor, having a first terminal coupled to the output of the first op amp, and a second terminal coupled to the second terminal of the fifth resistor; and
a third capacitor, having a first terminal coupled to the second terminals of the fifth and sixth resistors, and a second terminal coupled to the ground terminal.

5. The circuit of claim 1, further comprising:
a third switching device, having a first terminal coupled to the first power supply terminal, a second terminal, and a control terminal; and
a fourth switching device, having a first terminal coupled to the second terminal of the third switching device, and a second terminal coupled to the second power supply terminal;
a fourth resistor, having a first terminal coupled to the second terminal of the third switching device and a second terminal coupled to the inverting input of the first op amp;
a first inductor, having a first terminal coupled to the second terminal of the first switching device, and a second terminal coupled to the load terminal;
a second inductor, having a first terminal coupled to the second terminal of the third switching device, and a second terminal coupled to the load terminal;
a second capacitor, having a first terminal coupled to the load terminal and a second terminal coupled to a ground terminal; and
controller circuitry, having an input coupled to the load terminal, a first output coupled to the control terminal of the first switching device, and a second output coupled to the control terminal of the third switching device.

6. The circuit of claim 5, wherein the controller circuitry is configured to turn on the first and third switching devices in separate phases of each of a plurality of cycles.

7. The circuit of claim 6, further comprising:
a second op amp, having an inverting terminal, a non-inverting terminal coupled to the load terminal, and an output coupled to the non-inverting terminal of the first op amp;
a second capacitor, having a first terminal coupled to the output of the second op amp, and a second terminal coupled to the inverting input of the second op amp;
a fifth resistor, having a first terminal coupled to the output of the second op amp, and a second terminal coupled to the inverting input of the second op amp, the second capacitor and fifth resistor coupled in series;
a sixth resistor, having a first terminal coupled to the inverting input of the second op amp, and a second terminal;
a seventh resistor, having a first terminal coupled to the output of the first op amp, and a second terminal coupled to the second terminal of the sixth resistor; and
a third capacitor, having a first terminal coupled to the second terminals of the sixth and seventh resistors, and a second terminal coupled to the ground terminal.

8. The circuit of claim 1, further comprising:
controller circuitry, having an input coupled to the load terminal, and an output coupled to the control terminal of the first switching device.

9. The circuit of claim 1, wherein the first switching device is a transistor and the second switching device is a diode.

10. The circuit of claim 1, wherein the first switching device is a transistor;
and wherein the second switching device is a transistor, the transistor further having a control terminal coupled to an output of the controller circuitry.

11. A voltage converter circuit, comprising:
a switched-mode voltage converter, configured to switch a current at an output terminal responsive to a voltage at a load terminal; and
a ripple cancellation circuit, having inputs coupled to the output terminal and the load terminal, and an output coupled to the output terminal, the ripple cancellation circuit configured to output a cancellation current corresponding to an integration of a difference between the voltage at the load terminal and a voltage at the output terminal.

12. The circuit of claim 11, wherein the ripple cancellation circuit comprises:
a first operational amplifier, having a non-inverting input receiving the voltage at the load terminal, and having an inverting input and an output;
a first integrating feedback network coupled between the output of the first operational amplifier and the inverting input of the first operational amplifier;
a first resistor coupled between the load terminal and the output of the first operational amplifier; and
a second resistor coupled between the switching terminal and the inverting input of the first operational amplifier.

13. The circuit of claim 12, wherein the ripple cancellation circuit further comprises:
a second operational amplifier, having a non-inverting input coupled to the load terminal, an inverting input, and an output coupled to the non-inverting input of the first operational amplifier;
a third resistor, coupled between the inverting input of the second operational amplifier and the output of the first operational amplifier; and
a second integrating feedback network, coupled between the inverting input and the output of the second operational amplifier.

14. The circuit of claim 13, further comprising:
a fourth resistor, coupled in series with the third resistor between the inverting input of the second operational amplifier and the output of the first operational amplifier; and
a capacitor, coupled at a node between the third and fourth resistors.

15. The circuit of claim 11, further comprising:
an inductor, having a first terminal coupled to the output terminal, and a second terminal coupled to the load terminal;
a second capacitor, having a first terminal coupled to the load terminal, and a second terminal receiving a common potential.

16. A circuit, comprising:
a linear power amplifier, having an output coupled to a load terminal of the circuit;
a voltage converter, having an output coupled to the load terminal, and having a feedback input; and
a control loop circuit, having an input coupled to the load terminal, and an output coupled to the feedback input of the voltage converter;
wherein the voltage converter includes:
a first op amp, having an inverting input, a non-inverting input coupled to the load terminal, and an output;
a first resistor, having a first terminal coupled to the output of the first op amp, and a second terminal coupled to the inverting input of the op amp;
a second resistor, having a first terminal coupled to the voltage converter output, and a second terminal coupled to the inverting input of the first op amp;
a first capacitor, having a first terminal coupled to the output of the first op amp, and a second terminal coupled to the inverting input of the first op amp; and
a third resistor, having a first terminal coupled to the output of the first op amp, and a second terminal coupled to the load terminal.

17. The circuit of claim 16, further comprising:
an inductor, having a first terminal coupled to the voltage converter output, and a second terminal;
a second capacitor, having a first terminal coupled to the second terminal of the inductor, and a second terminal receiving a common potential;
a first switch, having a first terminal coupled to the second terminal of the inductor, a second terminal coupled to the load terminal, and a control terminal;
a second switch, having a first terminal coupled to the linear power amplifier output, a second terminal coupled to the load terminal, and a control terminal; and
mode control circuitry, having an output coupled to the control terminals of the first and second switches.

18. The circuit of claim 16, wherein the voltage converter further includes:
a first switching device, having a first terminal coupled to a first power supply terminal, a second terminal coupled to the voltage converter output, and a control terminal; and
a second switching device, having a first terminal coupled to the second terminal of the first switching device, and a second terminal coupled to a second power supply terminal.

19. The circuit of claim 18, wherein the voltage converter further includes:
a second op amp, having an inverting terminal, a non-inverting terminal coupled to the load terminal, and an output coupled to the non-inverting terminal of the first op amp;
a fourth resistor, having a first terminal coupled to the output of the first op amp, and a second terminal coupled to the inverting input of the second op amp; and
a second capacitor, having a first terminal coupled to the output of the second op amp, and a second terminal coupled to the inverting input of the second op amp.

20. The circuit of claim 18, wherein the voltage converter further includes:
a second op amp, having an inverting terminal, a non-inverting terminal coupled to the load terminal, and an output coupled to the non-inverting terminal of the first op amp;
a second capacitor, having a first terminal coupled to the output of the second op amp, and a second terminal coupled to the inverting input of the second op amp;
a fourth resistor, having a first terminal coupled to the output of the second op amp, and a second terminal coupled to the inverting input of the second op amp, the second capacitor and fourth resistor coupled in series;
a fifth resistor, having a first terminal coupled to the inverting input of the second op amp, and a second terminal;
a sixth resistor, having a first terminal coupled to the output of the first op amp, and a second terminal coupled to the second terminal of the fifth resistor; and
a third capacitor, having a first terminal coupled to the second terminals of the fifth and sixth resistors, and a second terminal coupled to the ground terminal.
